(19) United States
(12) Patent Application Publication
(10) Pub. No.: US 2013/0248901 A1
(43) Pub. Date: Sep. 26, 2013

(54) LIGHT-EMITTING DIODE COMPRISING DIELECTRIC MATERIAL LAYER AND MANUFACTURING METHOD THEREOF

(71) Applicant: FORMOSA EPITAXY INCORPORATION, TAOYUAN (TW)

(72) Inventors: WEN-YU LIN, Taichung City (TW); LIANG-WEN WU, TAOYUAN (TW)

(73) Assignee: FORMOSA EPITAXY INCORPORATION, TAOYUAN (TW)

(21) Appl. No.: 13/847,444

(22) Filed: Mar. 19, 2013

(30) Foreign Application Priority Data
Mar. 21, 2012 (TW) 101109719

(51) Int. Cl. H01L 33/24

(52) U.S. Cl. CPC H01L 33/24
USPC 257/95; 438/29

(57) ABSTRACT

Disclosed is a light-emitting diode with a semiconductor layer including dielectric material layer, and a manufacturing method thereof for increasing the external quantum efficiency. The semiconductor layer includes a non-flat structure having a plurality of recess regions, and at least one dielectric material layer disposed within each recess region, the dielectric material layer has a generally inverted pyramid shape or a ball shape, and a portion of the non-flat structure is exposed outside the dielectric material layer. Photons emitted from the active layer are scattered by the dielectric material layer as photon scattering structure, and are guided by the inclined internal side faces of the recess regions so that the probability of photons escaping from the light-emitting diode is increased, and thus total internal reflection is reduced, thereby increasing the extraction efficiency and hence the external quantum efficiency.

### BACKGROUND OF THE INVENTION

1. Field of the Invention

The present invention generally relates to a light-emitting diode (LED) with a semiconductor layer including dielectric material layer and a manufacturing method thereof, and particularly relates to a light-emitting diode capable of reducing total internal reflection and increasing the external quantum efficiency.

2. The Prior Arts

GaN-based light-emitting diodes (LEDs) can be manufactured for emitting a variety of light by controlling the composition of materials, and related technologies have therefore become the focus of active research and development in industry and academia in recent years. One research priority of academia and industry for GaN-based LEDs is to understand the luminous characteristics of GaN-based LEDs and to propose a method for increasing the external quantum efficiency and brightness of GaN-based LEDs. GaN-based LEDs with high external quantum efficiency and high brightness can be effectively used in outdoor display panel, automotive lighting, and other applications.

The external quantum efficiency of GaN-based LEDs is mainly related to the internal quantum efficiency and the extraction efficiency of GaN-based LEDs. The internal quantum efficiency is related to the probability of photon generation through recombination of electrons and holes in the active layer of a GaN-based LED. The more easily electrons and holes recombine, the more photons generated, the higher the internal quantum efficiency obtained, and also the higher the external quantum efficiency achieved. The extraction efficiency is related to the probability of photons not being absorbed by and successfully escaping from the GaN-based LED. The more photons escaping to the outside of the GaN-based LED, the higher the extraction efficiency obtained, and also the higher the external quantum efficiency achieved.

The extraction efficiency mainly depends on the type of top surface layer and the refractive index thereof. The refractive indices of GaN and air are 2.5 and 1, respectively. Because of the higher refractive index, total internal reflection occurs easily inside known GaN-based LEDs. The generated photons can not easily escape to the outside of the GaN-based LED due to the occurrence of total internal reflection. The extraction efficiency of GaN-based LEDs is therefore limited, and a structure for reducing total internal reflection is needed.

For example, there is a method for forming a texture pattern on the substrate in U.S. Pat. No. 7,683,386. In this method, a protective film is formed on the substrate followed by photolithography and reactive ion etching (RIE) to form the texture pattern on the substrate, and then the area not covered by the protective film is removed by RIE, thereby forming the texture pattern on the substrate.

However, the shortcomings in the above prior art is that the texture pattern is formed on the substrate by a photolithographic process, so that the shape of the texture pattern is limited to regular shapes such as circle, square, long strip, etc., and thus the improvement in extraction efficiency is limited. Therefore, there is a need to provide a method for manufacturing a structure with high distribution density to maximize the effect of photon scattering, without the necessity of a photolithographic process.

### SUMMARY OF THE INVENTION

An objective of the present invention is to provide a light-emitting diode with increased external quantum efficiency, wherein a semiconductor layer of the light-emitting diode includes at least one dielectric material layer disposed therein and function as photon scattering structure in order to increase the probability of photons escaping from the light-emitting diode, and thus total internal reflection is reduced, thereby increasing the extraction efficiency and hence the external quantum efficiency.

In order to achieve the above objective, in one aspect, the present invention provides a light-emitting diode with a semiconductor layer including dielectric material layer, which comprises: a semiconductor layer including a non-flat structure having a plurality of recess regions, and at least one dielectric material layer disposed within each recess region, the dielectric material layer has a generally inverted pyramid shape or a ball shape, and a portion of the non-flat structure is exposed outside the dielectric material layer.

Another objective of the present invention is to provide a light-emitting diode with a semiconductor layer including dielectric material layer, wherein a high distribution density dielectric material layer is disposed directly within recess regions of a non-flat structure so that a photolithographic process can be omitted, and thereby the manufacture time and cost are reduced. In addition, the light scattering effect can be maximized due to the high distribution density dielectric material layer.

In order to achieve the above objective, in another aspect, the present invention provides a method for manufacturing a light-emitting diode with a semiconductor layer including dielectric material layer, comprising the following steps: forming a first portion of a semiconductor layer upon a substrate; treating the top surface of the first portion of the semiconductor layer into a non-flat structure having a plurality of recess regions; forming at least one dielectric material layer upon the non-flat structure; reducing the dielectric material layer to the extent a portion of the non-flat structure can be exposed; and forming a second portion of the semiconductor layer on the non-flat structure and the dielectric material layer.

Accordingly, the present invention can solve the problems of the prior art. In the present invention, the probability of photons escaping from the light-emitting diode is increased, and thus total internal reflection is reduced, thereby increasing the extraction efficiency and hence the external quantum efficiency.

The foregoing and other features, aspects and advantages of the present invention will be better understood from a careful reading of a detailed description provided herein below with appropriate reference to the accompanying drawings.

### BRIEF DESCRIPTION OF THE DRAWINGS

The accompanying drawings, which are incorporated in and constitute a part of this specification, illustrate embodiments consistent with the invention and, together with the description, serve to explain the principles of the invention.

FIG. 1 shows a schematic cross-sectional view illustrating a semiconductor layer including dielectric material layer for a light-emitting diode according to one embodiment of the present invention.

FIG. 2 shows a schematic view illustrating a light-emitting diode with a semiconductor layer including dielectric material layer according to one embodiment of the present invention.

FIG. 3 shows a schematic cross-sectional view illustrating a method for manufacturing a semiconductor layer including dielectric material layer for a light-emitting diode according to one embodiment of the present invention.

FIG. 4 shows a schematic cross-sectional view illustrating a method for manufacturing a semiconductor layer including dielectric material layer for a light-emitting diode according to one embodiment of the present invention.

FIG. 5 shows a schematic cross-sectional view illustrating a method for manufacturing a semiconductor layer including dielectric material layer for a light-emitting diode according to one embodiment of the present invention.

FIG. 6 shows a schematic cross-sectional view illustrating a method for manufacturing a semiconductor layer including dielectric material layer for a light-emitting diode according to one embodiment of the present invention.

### DETAILED DESCRIPTION OF THE PREFERRED EMBODIMENT

In the following detailed description, for purposes of explanation, numerous specific details are set forth in order to provide a thorough understanding of the disclosed embodiments. It will be apparent, however, that one or more embodiments can be practiced without these specific details. In other instances, well-known structures and devices are schematically shown in order to simplify the drawing.

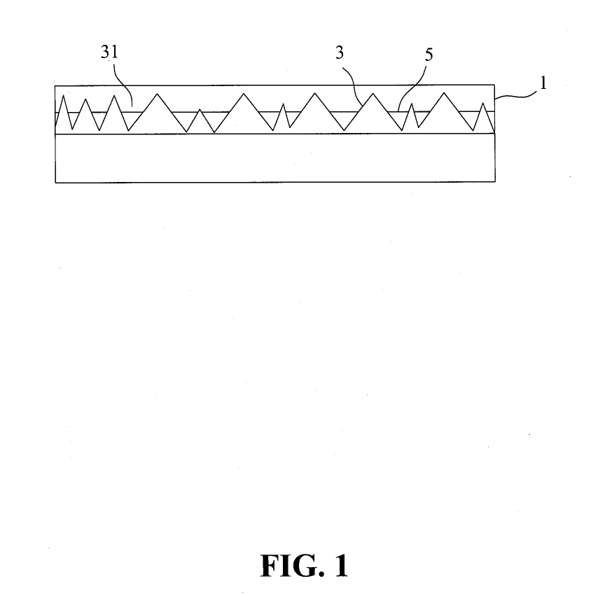

FIG. 1 shows a schematic cross-sectional view illustrating a semiconductor layer including dielectric material layer for a light-emitting diode (LED) according to one embodiment of the present invention. As shown in FIG. 1, an LED according to the present invention comprises a semiconductor layer 1 including dielectric material layer 5, and the semiconductor layer 1 can include at least one material selected from the group comprising an element semiconductor, a compound semiconductor, or other suitable semiconductor materials, wherein the compound semiconductor can be selected from binary, ternary or quaternary III-V compound semiconductor materials such as gallium arsenide (GaAs), gallium nitride (GaN) or other compound semiconductors.

The semiconductor layer 1 includes a first portion, wherein the top surface of the first portion is treated into a non-flat structure 3 having a plurality of recess regions 31, and at least one dielectric material layer 5 is disposed within each recess region 31, as well as a second portion disposed on the non-flat structure the said dielectric material layer. The dielectric material layer 5 is not allowed to cover the non-flat structure 3; in other words, a portion of the non-flat structure 3 shall be exposed outside the dielectric material layer 5.

The dielectric material layer 5 has a generally inverted pyramid shape or a ball shape. The dielectric material layer 5 functions as a photon scattering center to scatter photons emitted from the active layer (not shown in the figures) in order to decrease the occurrence of total internal reflection and to increase the extraction efficiency. Furthermore, the inclined internal side faces of the recess regions 31 can guide the photons toward the outside of the light-emitting diode, so that the extraction efficiency can be effectively increased. The preferred materials for the dielectric material layer 5 include at least one component selected from the group comprising silicon dioxide (SiO₂), silicon nitride (SiNₓ), tantalum pentoxide (Ta₂O₅), titanium dioxide (TiO₂), zinc oxide (ZnO), hafnium oxide (HfO₂), magnesium peroxide (MgO₂), magnesium nitride (MgNₓ), and other materials having wide energy bandgap in order to prevent photon absorption, high temperature resistance, and refractive index different from that of the first portion or the second portion of the semiconductor layer 1.

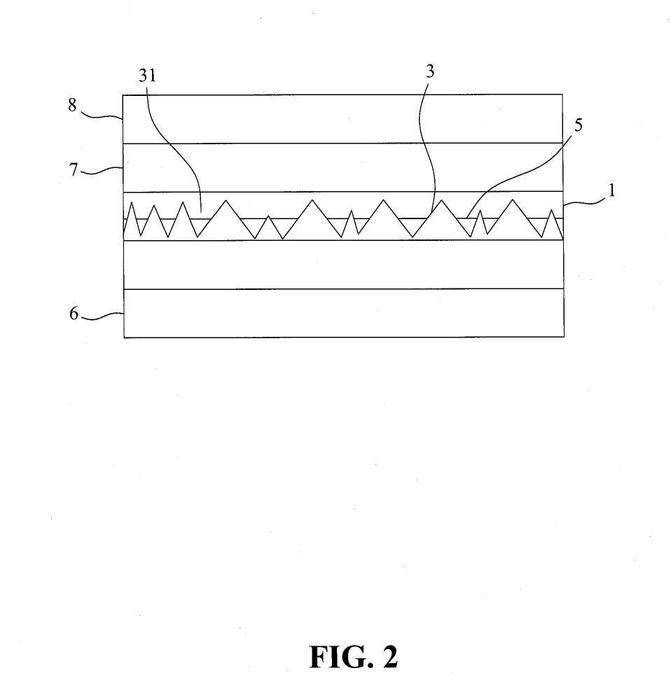

FIG. 2 shows a schematic view illustrating a light-emitting diode with a semiconductor layer including dielectric material layer according to one embodiment of the present invention. As shown in FIG. 2, the semiconductor layer 1 is disposed on a substrate 6, and then an active layer 7 and a first semiconductor layer 8 are sequentially disposed on the semiconductor layer 1.

When current passes through the active layer 7, electrons and holes in the active layer 7 recombine and energy is released in the form of emitted photons. The photons in the upper half portion of the active layer 7 have the opportunity to escape swiftly from the light-emitting diode, but the photons in the lower half portion of the active layer 7 move toward the substrate 6. In the present invention, there is at least one dielectric layer 5 disposed within the semiconductor layer 1, and the photons emitted from the active layer 7 can be scattered by the dielectric layer 5 as photon scattering structure, and the scattered photons can be reflected and guided by the inclined internal side faces of the recess regions 31, and then escape from the light-emitting diode, and thus the total internal reflection effect is reduced, thereby increasing the extraction efficiency.

If the semiconductor layer 1 is an n-type GaN-based semiconductor, the first semiconductor layer 8 will be a p-type GaN-based semiconductor. If the semiconductor layer 1 is a p-type GaN-based semiconductor, the first semiconductor layer 8 will be an n-type GaN-based semiconductor. However, the various examples of the semiconductor layer 1 with dielectric layer 5 which are able to scatter light out of the light-emitting diode all fall within the scope of the present invention.

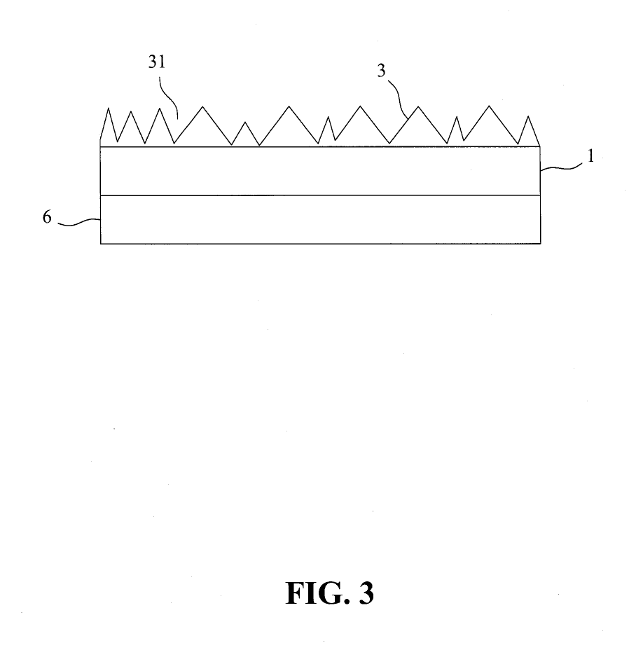

FIGS. 3-6 show the schematic cross-sectional views illustrating a method for manufacturing a semiconductor layer including dielectric material layer for a light-emitting diode according to one embodiment of the present invention. As shown in FIG. 3, a first portion of a semiconductor layer 1 is formed upon a substrate 6, wherein the top surface of the first portion of the semiconductor layer 1 is treated into a non-flat structure 3, the non-flat structure 3 has a plurality of recess regions 31, and the recess regions 31 are distributed over the non-flat structure 3. The substrate 6 can be selected from a substrate base, an epitaxial layer, a metal layer, an active layer or other suitable component. The semiconductor layer 1 can include at least one material selected from the group comprising an element semiconductor, a compound semiconductor or other suitable semiconductor materials, wherein the compound semiconductor can be selected from binary, ternary or quaternary III-V compound semiconductor materials such as gallium arsenide (GaAs), gallium nitride (GaN) or other compound semiconductors.

The non-flat structure 3 is formed by performing a surface treatment on the first portion of the semiconductor layer 1. For example, the first portion of the semiconductor layer 1 is grinded to form an irregular non-flat structure thereon, or the first portion of the semiconductor layer 1 is reactive-ion etched (RIE) to form a regular or periodic non-flat structure thereon.

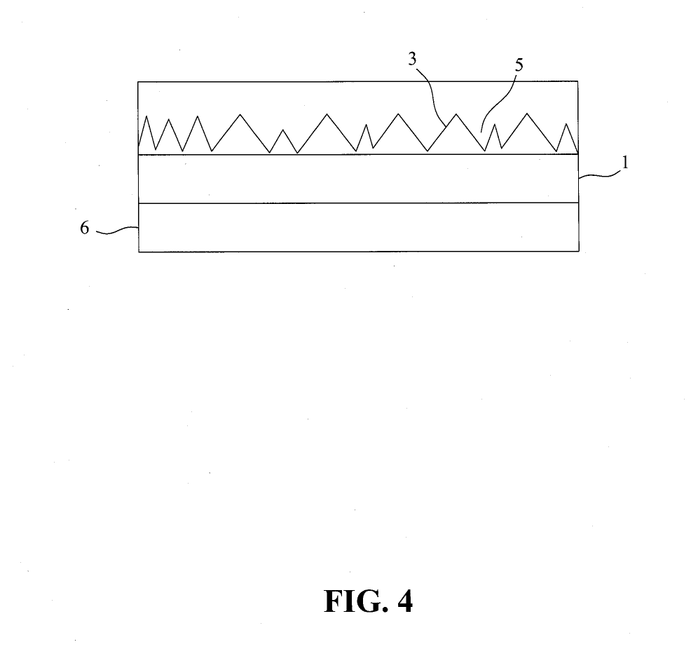

Then, as shown in FIG. 4, at least one dielectric material layer 5 is formed upon the non-flat structure 3. The preferred materials of the dielectric material layer 5 include at least one component selected from the group comprising silicon dioxide (SiO₂), silicon nitride (SiNₓ), tantalum pentoxide (Ta₂O₅), titanium dioxide (TiO₂), zinc oxide (ZnO), hafnium dioxide (HfO₂), magnesium peroxide (MgO₂), magnesium nitride (MgNₓ), and other materials having wide energy bandgap in order to prevent photon absorption, high temperature resistance and refractive index different from that of the first portion or the second portion of the semiconductor layer 1.

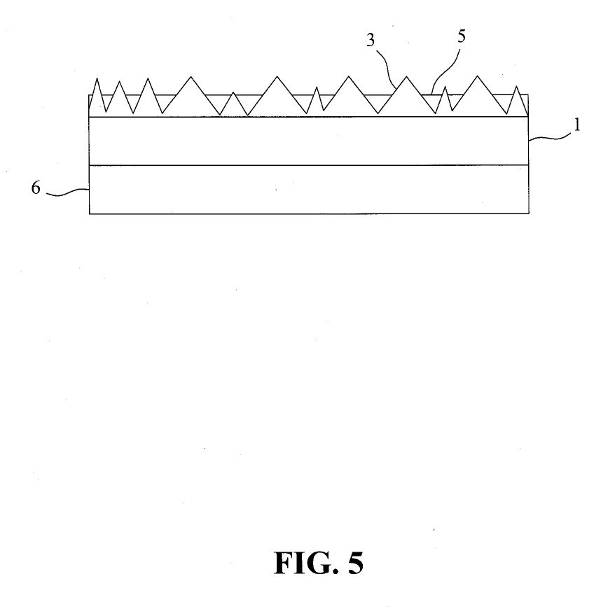

Then, as shown in FIG. 5, part of the dielectric material layer 5 is etched using the inductively coupled plasma reactive ion etching (ICP-RIE) process to expose a portion of the non-flat structure 3, wherein the dielectric layer 5 within each recess region 31 preferably has an inverted pyramid shape.

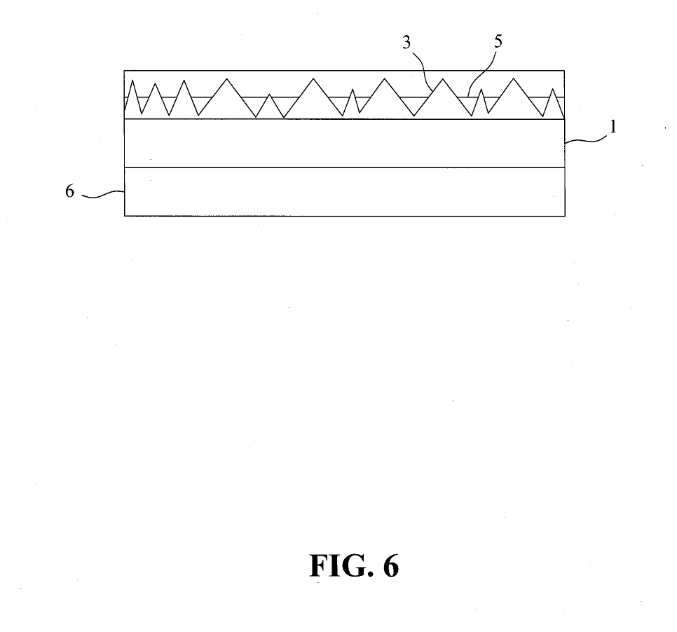

Finally, as shown in FIG. 6, the second portion of the semiconductor layer 1 is formed upon the non-flat structure 3 and the dielectric material layer 5. The manufacturing process of the present invention can be integrated with the manufacturing process of light-emitting diodes to effectively increase the external quantum efficiency of light-emitting diodes.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A light-emitting diode comprising:
a semiconductor layer comprising:
a first portion, wherein the top surface of said first portion is treated into a non-flat structure having a plurality of recess regions;
at least one dielectric material layer disposed within each recess region; and
a second portion disposed on said non-flat structure and said dielectric material layer,
wherein a portion of said non-flat structure is exposed outside said dielectric material layer.

2. The light-emitting diode of claim 1, wherein said semiconductor layer is disposed on a substrate.

3. The light-emitting diode of claim 2, wherein said substrate is selected from a substrate base, an epitaxial layer, a metal layer, or an active layer.

4. The light-emitting diode of claim 2, wherein said semiconductor layer is interposed between said substrate and an active layer.

5. The light-emitting diode of claim 1, wherein said semiconductor layer includes at least one material selected from the group comprising an element semiconductor and a compound semiconductor.

6. The light-emitting diode of claim 1, wherein said non-flat structure is irregular.

7. The light-emitting diode of claim 1, wherein said non-flat structure is regular or periodic.

8. The light-emitting diode of claim 1, wherein said recess regions have inclined internal side faces.

9. The light-emitting diode of claim 1, wherein said dielectric material layer includes at least one material with wide energy bandgap.

10. The light-emitting diode of claim 1, wherein the refractive index of said dielectric material layer is different from that of said first portion or said second portion of said semiconductor layer.

11. The light-emitting diode of claim 1, wherein said dielectric material layer includes at least one material selected from the group comprising silicon dioxide, silicon nitride, tantalum pentoxide, titanium dioxide, zinc oxide, hafnium oxide, magnesium peroxide, and magnesium nitride.

12. The light-emitting diode of claim 1, wherein said dielectric material layer has a generally inverted pyramid shape or a ball shape.

13. A method for manufacturing a light-emitting diode, comprising:
forming a first portion of a semiconductor layer upon a substrate;
treating the top surface of said first portion of the semiconductor layer into a non-flat structure having a plurality of recess regions;
forming at least one dielectric material layer upon said non-flat structure;
reducing part of said dielectric material layer to expose a portion of said non-flat structure; and
forming a second portion of said semiconductor layer upon said non-flat structure and said dielectric material layer.

14. The method of claim 13, further comprising:
forming an active layer upon said semiconductor layer.

15. The method of claim 13, wherein said substrate is selected from a substrate base, an epitaxial layer, a metal layer, or an active layer.

16. The method of claim 13, wherein said semiconductor layer includes at least one material selected from the group comprising an element semiconductor and a compound semiconductor.

17. The method of claim 13, wherein said non-flat structure is irregular.

18. The method of claim 13, wherein said non-flat structure is regular or periodic.

19. The method of claim 13, wherein said recess regions have inclined internal side faces.

20. The method of claim 13, wherein said dielectric material layer includes at least one material with wide energy bandgap.

21. The method of claim 13, wherein the refractive index of said dielectric material layer is different from that of said first portion or said second portion of said semiconductor layer.

22. The method of claim 13, wherein said dielectric material layer includes at least one material selected from the group comprising silicon dioxide, silicon nitride, tantalum pentoxide, titanium dioxide, zinc oxide, hafnium dioxide, magnesium peroxide, and magnesium nitride.

23. The method of claim 13, wherein said dielectric material layer is reduced using an inductively coupled plasma reactive ion etching process.

24. The method of claim 13, wherein said dielectric material layer has a generally inverted pyramid shape or a ball shape.
